(19) United States
(12) Patent Application Publication
(10) Pub. No.: US 2005/0151142 A1
(43) Pub. Date: Jul. 14, 2005

(54) LED substrate

(75) Inventor: Sadato Imai, Yamanashi-ken (JP)

Correspondence Address: DENNISON, SCHULTZ, DOUGHERTY & MACDONALD, 1727 KING STREET, SUITE 105, ALEXANDRIA, VA, 22314, US

(73) Assignee: Citizen Electronics Co., Ltd.

(21) Appl. No.: 11/029,389

(22) Filed: Jan. 6, 2005

(30) Foreign Application Priority Data
Jan. 8, 2004 (JP) 2004-002527

(51) Int. Cl. H01L 27/15

(52) U.S. Cl. 257/81; 257/100; 257/433

(57) ABSTRACT

An insulating substrate made of insulating material is used. A pair of electrode patterns are formed on the surface of the insulating substrate, and a pair of through-holes are formed in the insulating substrate. A resin is mounted on the insulating substrate to close an opening of each of the through-holes. Two portions of the resin are removed to form a pair of electric conduction parts necessary for mounting an LED element.

### BACKGROUND OF THE INVENTION

The present invention relates to a substrate on which a light emitting diode (LED) element is mounted thereby to form an LED of the surface mounting type, and more particularly, to a substrate having through-holes.

Due to small power consumption and ease for mounting, an LED of the surface mounting type has been extensively used as a light source of a back light for liquid crystal displays and surface switches. The LED is formed by mounting an LED element or an LED chip on an LED substrate and the LED element or a chip has a p-n junction of p-type semiconductor layer and n-type semiconductor layer. Japanese Patent Laid-Open No. 8-213660 discloses in FIG. 15 thereof, an example of such a known LED substrate for surface mounting.

FIG. 5a is a sectional view of an LED substrate 110 similar to the LED substrate of Japanese Patent Laid-Open No. 8-213660 and FIG. 5b is a sectional view of an LED 150 employing the LED substrate 110.

Referring to FIG. 5a, the LED substrate 110 comprises a rectangular insulating substrate 102 made of an insulation material, and connecting electrodes 103, 104 formed on the substrate 102. Each of the electrodes 103 and 104 extends from the upper surface to the lower surface of the insulating substrate 102 through the side surfaces.

In order to manufacture an LED using the LED substrate 110, as shown in FIG. 5b, on the upper surface of the insulating substrate 102, that is, on the electrode 103 in the present example, an LED element 101 is adhered, and electrically connected to the electrodes 103 and 104 with wires 106. An encapsulant 104 of such as resin and silicone is formed on the insulating substrate 102 by molding, thereby covering and protecting the LED element 101, wires 106, and the pair of electrodes 103 and 104. Thus, the surface-mounted LED 150 generally in use is formed.

However, when encapsulating the LED with the encapsulant 107, in order to prevent the melted encapsulant 107 from flowing downward to the side surfaces of the insulating substrate 102, a space surrounding the encapsulant 107 on the upper surface of the insulating substrate is necessary so that a jig may be provided on the substrate. Thus, the circumference of the LED 150 is increased so that the mounting space for a jig is increased, which is a drawback in rendering the device in which the LED is mounted small.

In order to resolve the problem, Japanese Patent Application Laid-Open 8-107161 discloses in FIG. 7 thereof, an LED substrate similar to an LED substrate 120 shown in FIGS. 6a to 6c.

FIG. 6a is a sectional view of the LED substrate 120 and FIG. 5b is a sectional view of an LED aggregation 160S using the LED substrate 120. As shown in FIG. 5b, the LED aggregation 160S comprises a plurality of LED divisions each of which is detached from one another at the last manufacturing step to form individual LED 160 shown in FIG. 6c.

Referring to FIGS. 6a and 6b, the LED aggregation 160S comprises an insulating substrate 122, through-holes 128 drilled in the insulating substrate 122 at every border between adjacent divisions of each individual LED, and connecting electrodes 123 and 124 formed on the upper surface of the insulating substrate 122 and extended to the underside thereof through the through-holes 128. The electrodes right of the through-hole 128 are designated by the reference 123 and the electrodes left thereof by 124 in the figure for the ease of explanation. A dry film 125 is adhered to the upper surface of the connecting electrodes 123 and 124 to close the openings of the through-holes 128.

Referring to FIG. 6b, an LED element 101 is mounted on the LED substrate 120 at each LED division, that is, on the connecting electrode 123 in the present example. The mounted LED element 101 is connected to the connecting electrodes 123 and 124 by wires 106. An encapsulant 127 of transparent molding resin is molded on the upper surface of the LED aggregation 160S so as to encapsulate the aggregation. Since each of the openings of the through-holes 128 is covered by the dry film 125, the melted encapsulant 127 is prevented from leaking through the through-holes 128 to the underside of the insulating substrate 122. The LED aggregation 160S is thus formed.

The LED aggregation 160S is then diced at lines passing through the through-holes 128 shown by the dotted lines in

FIG. 5b, so that a plurality of individual LEDs 160 as shown in FIG. 6c are formed.

In accordance with the construction of the LED 160, in each of the connecting electrodes 123 and 124, portions on the upper surface and the lower surface of the substrate are electrically connected to each other through the through-hole 128 so that there is no need to provide a space around the encapsulant 127 on the insulating substrate 122 as in the case of LED 150 in FIG. 5b. Accordingly, the size of the LED in plan view is decreased.

However, since a certain adhesive force is necessary between the dry film 125 and the insulating substrate 122, or between the dry film 125 and the connecting electrodes 123 and 124 on the substrate 122, a large adhering area is required. Thus, there is a limit in miniaturizing the LED 160. In addition, when forming the connecting electrodes 123 and 124 on the surface of the substrate by plating, upon forming patterns with the dry film 125 by photo-etching, resist may not be strong enough to protect the dry film, so that the structure shown in FIG. 6a cannot be provided.

In order to resolve the problem, Japanese Patent Application Laid-Open 2001-148517 has proposed an LED substrate disclosed in FIG. 8 thereof, similar to an aggregation 130 of LED substrates shown in FIGS. 7a to 7c. On the LED substrate, a copper foil is adhered.

As shown in FIG. 7b, an LED aggregation 170S comprises a plurality of LED divisions each of which is separated from one another at the last manufacturing step to form an individual LED 170 which is shown in FIG. 7c.

Referring to FIG. 7a, the aggregation 130 of LED substrates comprises an insulating substrate 132, through-holes 138 drilled in the insulating substrate 132 at every border between adjacent divisions, and copper foil patterns 133 formed on the insulating substrate 132 to cover the openings of the through-holes 138. Surface plated portions 135a and 135b are formed on the copper foil patterns 133 for bonding. There are formed underside plated portions 134 extending from the inner wall of each through-hole 138 including the portion covered by the copper foil pattern 133, to the underside of the insulating substrate 132.

Referring to FIG. 7b wherein the procedure for manufacturing an LED as a surface-mounted electronic device on aggregation 130 of the LED substrates is shown, an LED element 101 is mounted on the aggregation 130 of LED substrates, that is, on the copper foil pattern 133 in the figure, at each LED division. The mounted LED 101 is electrically connected to each of the surface plated portions 135a and 135b by wires 106. An encapsulant 137 of transparent molding resin is applied in the same manner as the encapsulant 127 in FIG. 6b. Since the openings of the through-holes 138 are sealed by the copper foil pattern 133, the molding resin for forming the encapsulant 137 is prevented from leaking through the through-holes 138 to the side and lower surfaces of the insulating substrate 132. Thus, the aggregation 170S of LEDs is formed.

The aggregation 170S of LED is thereafter diced at lines passing through the through-holes 138 shown by the dotted lines in FIG. 7b so that a plurality of individual LEDs 170 are formed as shown in FIG. 7c. Each copper pattern 133 of the aggregation 170S of LEDs is divided by the dicing and a copper foil electrode 133a on the right side of the through-hole 138 and a copper foil electrode 133b on the left side are formed in the individual LED 170. The copper foil electrodes 133a and 133b are connected to the surface plated portions 135a and 135b, respectively.

The LED 170 thus formed by using the aggregation 130 of substrates on which the copper foil is adhered is more advantageous than the LED 160 shown in FIG. 6c in that the encapsulant 137 is prevented from entering the through-holes 138 with the copper foil patterns 133 without using the dry film 125 which is inferior in adhesive force. Thus a large space in plan view required for the dry film is omitted so that the manufactured electronic device can be miniaturized.

However, when dicing the aggregation 170S of LEDs at lines passing through the through-holes 138, the dicing stress often causes the copper foil patterns 133 to peel off from the insulating substrate 132.

### SUMMARY OF THE INVENTION

An object of the present invention is to provide an TED substrate used for mounting an LED element thereof and used for manufacturing an LED is sufficiently miniaturized.

According to the present invention, there is provided an LED substrate comprising an insulating substrate made of insulating material, through-holes formed in the insulating substrate, a pair of electrode patterns formed on the surface of the insulating substrate, each of the through-holes plated for electric conduction, and a resin mounted on the insulating substrate to close an opening of each of the through-holes, except a pair of electric conduction parts necessary for mounting an LED element.

In another aspect of the present invention, there is provided an LED substrate comprising an insulating substrate made of insulating material, through-holes formed in the insulating substrate, copper foil patterns provided for closing an opening of each of the through-holes, a pair of electrode patterns formed on the surface of the insulating substrate, each of the through-holes plated for electric conduction, and a resin mounted on the insulating substrate and on the copper foil patterns, except a pair of electric conduction parts necessary for mounting an LED element.

Each of the electrode patterns may be formed by copper plating, and each surface of the electric conductive parts is processed by plating for mounting an LED element.

The plating process in claim 3 is conducted by plating Ni, and then by plating Au or Ag.

A base of the electrode pattern is copper foil.

The insulating substrate is made of an insulating material such as glass-epoxy resin, BT resin and alumina.

Also, the insulating substrate may be made of insulating-material-layers which consist of glass-epoxy.

These and other objects and features of the present invention will become more apparent from the following detailed description with reference to the accompanying drawings.

### BRIEF DESCRIPTION OF DRAWINGS

FIG. 1a is a sectional view of an aggregation of LED substrates of a first embodiment of the present invention;

FIG. 1b is a plan view of the aggregation of LED substrates shown in FIG. 1a;

FIG. 1c is a sectional view of an aggregation of LEDs employing the aggregation of LED substrates shown in FIG. 1a;

FIG. 1d is a sectional view of an individual LED using an LED substrate separated from the aggregation of LED substrates shown in FIG. 1a;

FIGS. 2a to 2e are sectional views explaining a method for manufacturing the aggregation of LED substrates shown in FIG. 1a;

FIG. 3a is a sectional view of an aggregation of LED substrates of a second embodiment of the present invention;

FIG. 3b is a plan view of the aggregation of LED substrates;

FIG. 3c is a sectional view of an aggregation of LEDs employing the aggregation of LED substrates shown in FIG. 3a;

FIG. 3d is a sectional view of an individual LED using an LED substrate divided from the aggregation of LED substrates shown in FIG. 3a;

FIG. 4a is a plan view of an aggregation of LED substrates of a third embodiment of the present invention,

FIG. 4b is a sectional view of the aggregation of LED substrates taken along a line IV-IV of FIG. 4a;

FIG. 4c is a sectional view of the aggregation of LED substrates taken along a line V-V of FIG. 4a;

FIG. 4d is a perspective view of an LED manufactured using an LED substrate separated from the aggregation of LED substrates shown in FIG. 4a;

FIG. 4e is a plan view of the LED shown in FIG. 4d;

FIG. 5a is a sectional view of a conventional LED substrate;

FIG. 5b is a sectional view of a conventional LED using the LED substrate of FIG. 5a;

FIG. 6a is a sectional view showing an aggregation of another conventional LED substrates;

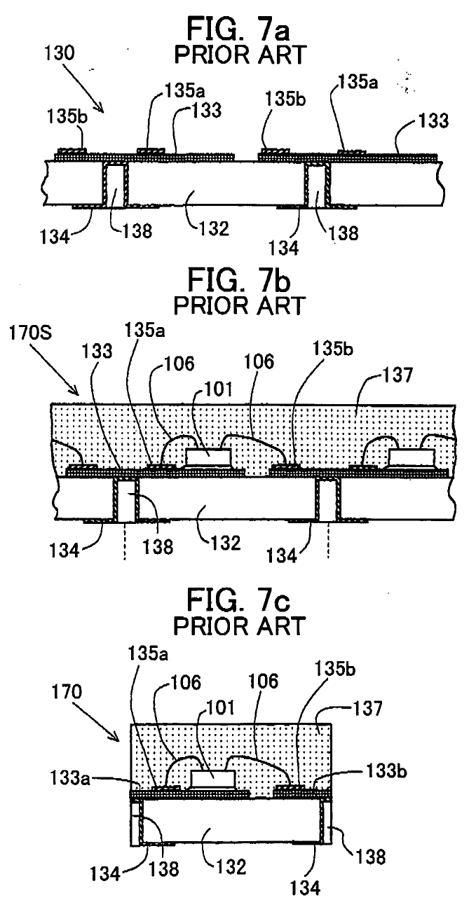

FIG. 5b is a sectional view of an aggregation of LEDs employing the aggregation of LED substrates shown in FIG. 6a;

FIG. 6c is a sectional view of a conventional LED using an LED substrate separated from the aggregation of LED substrates shown in FIG. 6a;

FIG. 7a is a sectional view showing an aggregation of another conventional LED substrates;

FIG. 7b is a sectional view of an LED aggregation employing the aggregation of LED substrates shown in FIG. 7a; and

FIG. 7c is a sectional view of a conventional LED manufactured with an LED substrate separated from the aggregation of LED substrates shown in FIG. 7a.

### DETAILED DESCRIPTION OF THE PREFERRED EMBODIMENT

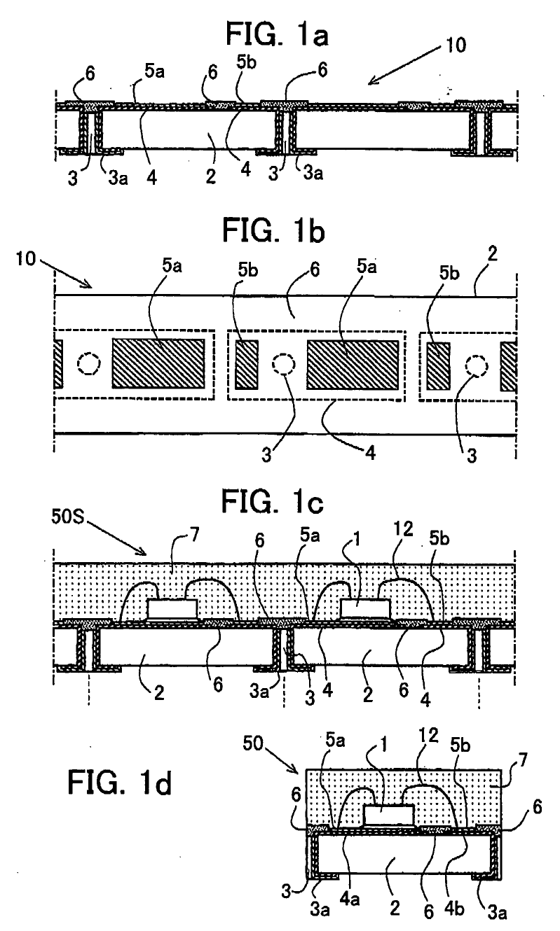

FIG. 1a is a sectional view of an aggregation 10 of LED substrates of a first embodiment of the present invention and FIG. 1b is a plan view of the aggregation 10 of LED substrates. The aggregation 10 of LED substrates is used to form an aggregation SOS of LEDs, the aggregation comprising a plurality of LED divisions as shown in FIG. 1c. The aggregation SOS is divided into individual LEDs 50, one of which is shown in FIG. 1d.

Referring to FIGS. 1a and 1b, the aggregation 10 of LED substrates comprises a rectangular insulating substrate 2 made of insulating material such as glass-epoxy resin, BT resin and alumina, through-holes 3 drilled in the insulating substrate 2 at every border between adjacent LED divisions, and base electrode patterns 4 for each individual LED formed on the insulating substrate 2 as conductive means. The insulating substrate may be made of insulating material layers which consist of glass-epoxy-resin layer and BT-resin layer. The base electrode patterns 4 provided on the insulating substrate are formed by means such as copper plating and are extended from the upper surface of the insulating substrate 2 to the lower surface thereof through the inner periphery of the through-holes 3. On the base electrode patterns 4 at the upper surface of the substrate 2, surface plated portions 5a and 5b are further formed by plating nickel (Ni) and then plating gold (Au) or silver (Ag). Each pair of surface plated portions 5a and 5b are disposed so as to oppose each other across the through-hole 3. Surface plated portions 3a made of material similar to those of the plated portions 5a and 5b are formed on the inner periphery of each through-hole 3 and are extended to cover the base electrode patterns 4 on the lower surface of the insulating substrate 2.

As shown in FIG. 1b, the surface plated portions 5a and 5b are formed at the opposite sides of each through-hole 3. A resin 6 made of high viscous and adhesive material such as prepreg, covers the upper surface of the insulating substrate 2 including the base electrode patterns 4 except the surface plated portions 5a and 5b.

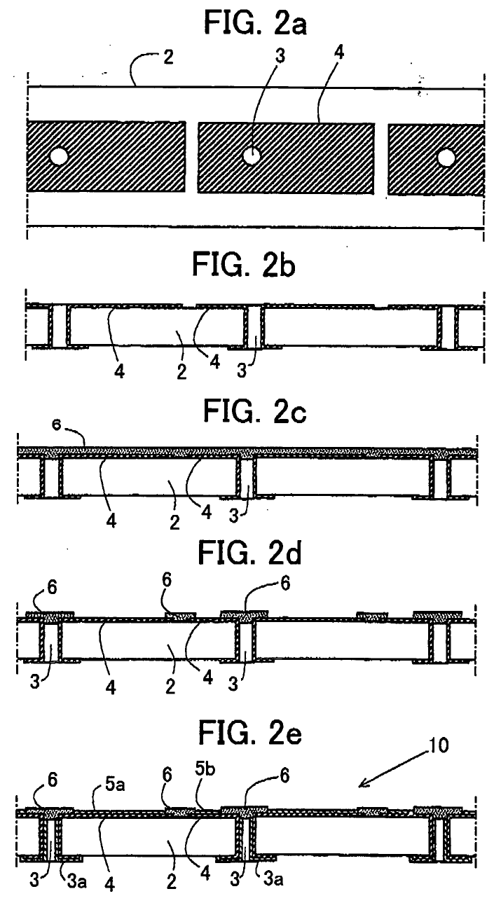

A method for forming the surface plated portions 5a and 5b and the resin 6 is described in detail with reference to FIGS. 2a to 2e.

Referring to FIGS. 2a and 2b, the base electrode patterns 4 are formed on the upper surface of the insulating substrate 2, inner periphery of the through-holes 3 and the lower surface of the substrate 2 by a known method. The resin 6 made of prepreg is then applied on the entire upper surface of the insulating substrate 2 as shown in FIG. 2c. Photo resists are formed on the resin 6 at places where the resin is to be remained except two portions. Thereafter, the two portions of the resin 6 is removed by a known method such as etching, thereby exposing the base electrode patterns 4 at the two portions as shown in FIG. 2d. The openings of the through-holes 3 are kept covered by the resin 6.

Plating layers are formed on the exposed electrode patterns 4 at the two portions by plating nickel, and then by plating gold (Au) or silver (Ag). Hence the surface plated portions 5a and 5b are formed as shown in FIG. 2e. At the same time, the surface plated portions 3a made of material similar to those of the plated portions 5a and 5b are formed on the inner periphery of the through-holes 3 and are extended to cover the base electrode patterns 4 and are extended to the lower surface of the insulating substrate 2. Thus, the aggregation 10 of LED substrates shown in FIGS. 1a and 1b is formed.

Referring to FIG. 1c, an LED element 1, which is a light emitting diode chip having p-n junction, is mounted on the aggregation 10 of LED substrates, in each LED division. The mounted LED 1 is electrically connected to the surface plated portions 5a and 5b by wires 12. An encapsulant 7 of molding resin is applied on the aggregation 10 of LED substrates so that the LED element 1 and the surface plated portions 5a and 5b are encapsulated. Thus, the aggregation SOS of LEDs is formed.

The aggregation 50S of LEDs is thereafter diced at lines passing through the through-holes 3 shown by the dotted lines in FIG. 1c, so that a plurality of LEDs 50 are formed as shown in FIG. 1d. By the dicing, each of the base electrode patterns 4 is divided at the through-hole 3 into right and left portions so as to become base electrode patterns 4a and 4b in the LED 50. In the LED 50, the base electrode pattern 4a is connected to the surface plated portion 5a while the base electrode pattern 4b is connected to the surface plated portion 5b.

Thus, the manufactured LED 50 is an LED suitable for surface-mounting where the surface plated portion 3a adjacent the divided through-hole 3 can be adhered by soldering and other means to an electrode of a circuit board (not shown). When a predetermined voltage is applied to the base electrode patterns 4a and 4b through the surface plated portions 3a, a predetermined current is applied to the LED element 1 to light the LED element 1. During the procedure for manufacturing the LED 50, when the encapsulant 7 is molded as shown in FIG. 1c, since the openings of the through-holes 3 are sealed by the resin 6 of prepreg, the molding resin is prevented from entering the through-holes 3 and leaking out to the side and lower surfaces of the insulating substrate 2. Moreover, the resin 6 covers a wide area except the surface plated portions 5a and 5b as shown in FIG. 1b. Accordingly, although the areas of the surface plated portions 5a and 5b, which are bonding areas for connecting the wires 12, are increased so that the widths of the resin 6 adjacent the through-holes 3 are decreased, the overall adherence of the resin 6 is kept sufficiently large. Accordingly, compared to the conventional LED substrate 120 in FIGS. 6a to 6c where the dry film 125 is adhered, the bonding area can be effectively increased without decreasing the adhesive force so that the utility efficiency of the electrode is increased, and as a result, the LED can be miniaturized.

Although the surface plated portions 5a and 5b are bonding areas for the wires in the first embodiment, the portions 5a and 5b may be mounting areas for bonding the LED element by die bonding or with wires.

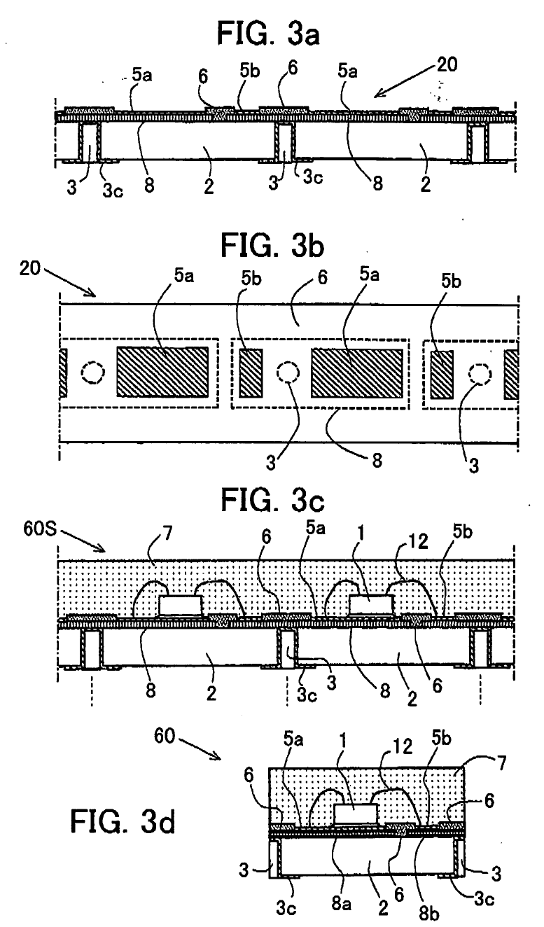

FIGS. 3a to 3d show the second embodiment of the present invention. FIG. 3a is a sectional view of an aggregation 20 of LED substrates according to the second embodiment, and FIG. 3b is a plan view of the aggregation 20 of LED substrates. The aggregation 20 of LED substrates is used to form an aggregation 60S of LEDs, the aggregation comprising a plurality of LED divisions as shown in FIG. 3c. The aggregation 60S of LEDs is divided into a plurality of individual LEDs 60, one of which is shown in FIG. 3d.

In the present embodiment, copper foil patterns 8 are provided instead of the base electrode patterns 4 of the first embodiment. Copper foil is pressed so as to adhere on the entire upper surface of the insulating substrate 2 having through-holes 3 formed therein. The foil is patterned by a known method such as etching, thereby to form the copper foil electrode patterns 8 to close the through-holes 3. The resin 6 of prepreg is applied on the electrode patterns 8 in the same manner as explained with reference to FIGS. 2a to 2e of the first embodiment so as to firmly cover the upper surface of the aggregation 20 of LED substrates including the electrode patterns 8 but excluding the areas for the surface plated portions 5a and 5b. The surface plated portions 5a and 5b are made of the same material as those of the first embodiment.

A surface plated portion 3c is formed on the inner periphery of each through-hole 3 including the portion covered by the electrode pattern 8, extending to the lower surface of the insulating substrate 2. The surface plated portion 3c is formed after the copper foil patterns 8 are formed. Although each surface plated portion 3c may be of the same material as the surface plated portions 5a and 5b, the plated portion 3c may be two-layer plating comprising a copper base layer and a plated layer formed on the base layer as in the first embodiment. The aggregation 20 of LED substrates is thus formed.

Referring to FIG. 3c, the LED element 1 is mounted on the aggregation 20 of substrates at each LED division. The mounted LED 1 is electrically connected to the surface plated portions 5a and 5b by wires 12. The aggregation 20 of LED substrates is sealed by the encapsulant 7 of molding resin so that the aggregation 60S of LEDs is formed.

The aggregation 60S of LEDs is thereafter diced at lines passing through the through-holes 3 shown by the dotted lines in FIG. 3c, so that a plurality of LEDs are formed and one of them is shown as the LED 60 in FIG. 3d. Each of the copper foil patterns 8 is divided at the through-hole 3 into right and left portions so as to become copper foil pattern 8a and copper foil pattern Bb in the LED 60. The copper foil pattern 8a is connected to the surface plated portion 5a and the copper foil pattern 8b is connected to the surface plated portion 5b.

When the LED 60 is surface-mounted on a circuit board (not shown), a predetermined voltage is applied to the LED element 1 through the copper foil patterns 8a and 8b, surface plated portions 5a and 5b, and the wires 12.

During the procedure for manufacturing the LED 60, since the openings of the through-holes 3 are covered by the copper foil pattern 8, the molding resin is prevented from entering the through-holes 3 and leaking out on the lower surface of the insulating substrate 2. Moreover, when dicing the aggregation 60S of LEDs, although stress is generated when the copper foil patterns 8 are cut, since the copper foil patterns 8 are firmly held by the resin 6 on the insulating substrate 2, the patterns 8 are not peeled off from the insulating substrate 2.

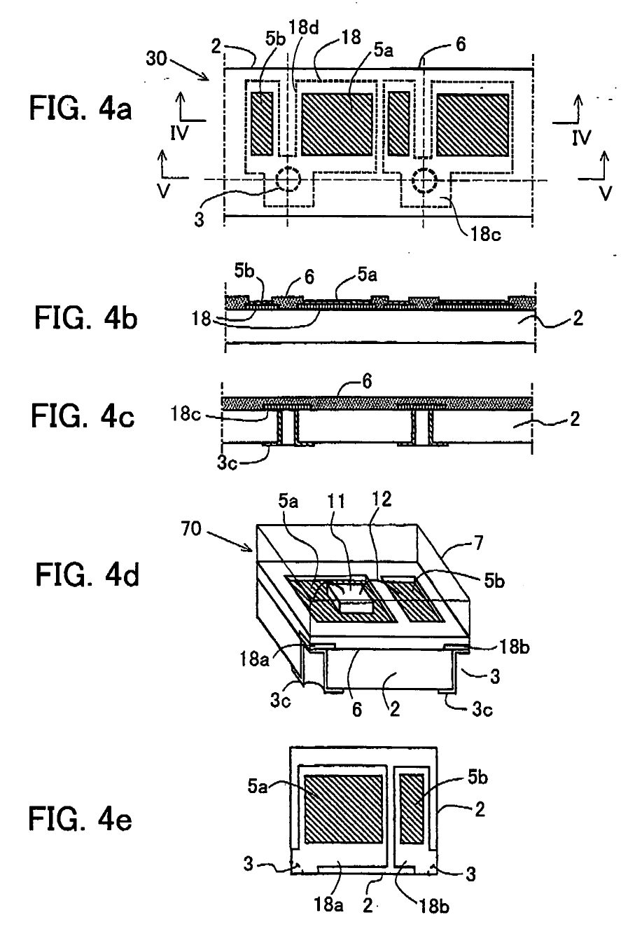

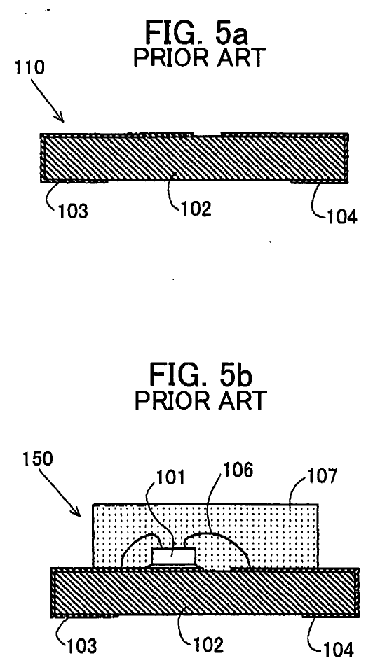

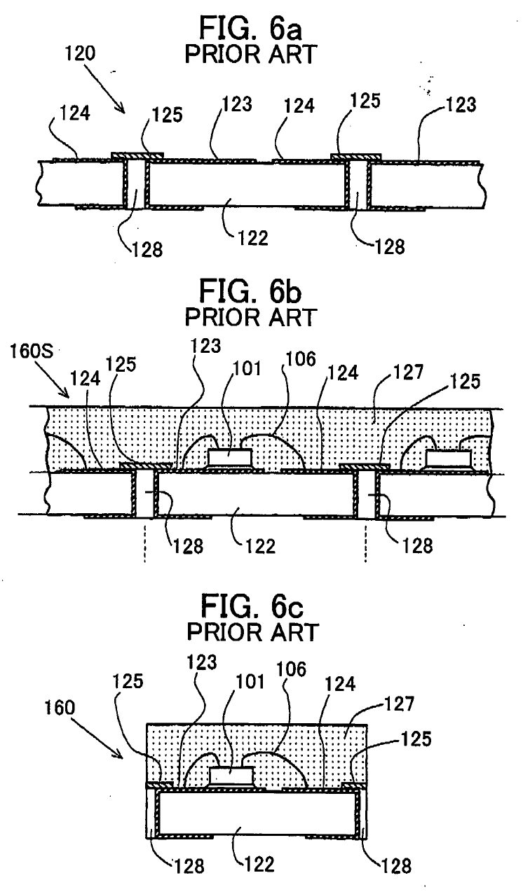

FIGS. 4a to 4e show the third embodiment of the present invention. FIG. 4a is a plan view of an aggregation 30 of LED substrates of the third embodiment, FIG. 4b is a sectional view of the aggregation 30 of LED substrates taken along a line IV-IV of FIG. 4a, and FIG. 4c is a sectional view of the aggregation 30 of LED substrates taken along a line V-V of FIG. 4a.

Referring to FIGS. 4a to 4c, on the insulating substrate 2 of the aggregation 30 of LED substrates, copper foil patterns 18 are formed on the insulating substrate 2 as in the second embodiment. The copper foil patterns 18 differ from the copper foil patterns 8 of the second embodiment shown in FIG. 3a in that the shapes thereof differ. Namely, each of the copper foil patterns 18 is shaped in plan view to form a projection 18c which covers the opening of one of the through-holes 3. The copper foil pattern 18 further has a recess 18d which is positioned to be formed between the surface plated portions 5a and 5b. Since the through-hole 3 is disposed distant from the center portion of the copper foil pattern 18, the usable area of the pattern is increased. Moreover, the construction aims to prevent, as much as possible, the end surfaces of the copper foil patterns 18 from being exposed when the aggregation 30 of LED substrates is diced to form a plurality of LEDs and one of the LEDs is shown as an LED 70 in FIG. 4d.

The other constructions of the aggregation 30 of LED substrates and the method for forming the same are the same as the aggregation 20 of LED substrates of the second embodiment.

The LED element 1 is mounted on the surface plated portion 5a of the aggregation 30 of LED substrates, connected to the surface plated portions 5a and 5b by wires 12, and sealed by the encapsulant 7 in the same manner as that shown in FIG. 3c. The aggregation 30 of LED substrates is diced at the lines shown by the dotted lines in FIG. 4a, thereby forming the LED 70 for surface-mounting as shown in FIG. 4d. Each through-hole 3 in the aggregation 30 of LED substrates is quartered and portions of the through-holes are located at two corners of the LED 70. Moreover, the copper foil pattern 18 is divided into a copper foil pattern 18a on the right side of the left border and a copper foil pattern 18b on the left side of the right border in FIG. 4e, so that the copper foil patterns 18a and 18b are not conductive with each other. Instead, the copper foil pattern 18a and 18b are connected to the surface plated portions 5a and 5b, respectively. Although the end surfaces of the copper foil patterns 18a and 18b are exposed adjacent the corner portions of the LED 70, end surfaces at other portions are positioned slightly inside of the edges of the insulating substrate 2 as shown in FIG. 4e. Thus the sides of the copper foil patterns are concealed by the resin 6 as shown in FIG. 4d and are not exposed. Hence the safety when handling the LED 70 is improved.

In addition, as can be seen from the plan view of the LED 70, the proportion of the areas of the surface plated portions 5a and 5b to the entire surface area of the LED 70 is increased so that the quantity of the reflected light radiated from the LED element 1 is increased. As a result, the quantity of the emitted light is increased. Other advantages of the third embodiment over the first embodiment are the same as those of the second embodiment.

In accordance with the present invention, resin such as prepreg having large viscosity and adhesive force covers the openings of the through-holes through which the LED substrate is diced to form a plurality of LEDs, and at the same time, seals and protects the conductive electrodes mounted on the insulating substrate of the LED. The conductive electrodes are not covered by the resin in their entirety, and the areas for wires for connecting the LED element are exposed. Not only does the resin such as prepreg prevent the melted molding resin for the encapsulant from flowing into the through-holes, the resin strengthens the adhesive force between the conductive electrodes and the insulating substrate, thereby preventing the electrodes to be removed from the insulating substrate at dicing. Hence problems inherent in the conventional LED substrate are reduced, thereby enabling to manufacture small and reliable LEDs for surface-mounting. In addition, the exposed area of the conductive electrode can be increased so that if plating is applied to the surface of the exposed area for mounting the LED element, reflective efficiency of the LED is increased thereby enabling to increase the emitting intensity.

Furthermore, in the case where the conductive electrodes are made of copper foil, a part of the resin layer of prepreg once formed on the electrodes can be removed by etching to expose areas necessary for connecting the LED element. The copper foil is advantageous in that it is strong enough to withstand etching.

While the invention has been described in conjunction with preferred specific embodiment thereof, it will be understood that this description is intended to illustrate and not limit the scope of the invention, which is defined by the following claims.

1. An LED substrate comprising:
an insulating substrate made of insulating material;
through-holes formed in the insulating substrate;
a pair of electrode patterns formed on the surface of the insulating substrate; and
a resin mounted on the insulating substrate, except a pair of electric conduction parts necessary for mounting an LED element, to close an opening of each of the through-holes.

2. An LED substrate comprising;
an insulating substrate made of insulating material;
through-holes formed in the insulating substrate;
copper foil patterns provided for closing an opening of each of the through-holes;
a pair of electrode patterns formed on the surface of the insulating substrate; and
a resin mounted on the insulating substrate and on the copper foil patterns, except a pair of electric conduction parts necessary for mounting an LED element.

3. The LED substrate according to claim 1 or 2 wherein each of the electrode patterns is formed by copper plating, each surface of the electric conductive parts is processed by plating for mounting an LED element.

4. The LED substrate according to claim 3 wherein the plating process is conducted by plating Ni, and then by plating Au or Ag.

5. The LED substrate according to claim 1 or 2 wherein a base of the electrode pattern is copper foil.

6. The LED substrate according to claim 1 or 2 wherein the insulating substrate is made of insulating material selected from glass-epoxy resin, BT resin and alumina.

7. The LED substrate according to claim 1 or 2 wherein the insulating substrate is made of insulating-material layers which consist of glass-epoxy-resin layer and BT-resin layer.
